(19) United States
(12) Patent Application Publication
(10) Pub. No.: US 2024/0103473 A1
(43) Pub. Date: Mar. 28, 2024

(54) TRANSMISSION UNIT AND METHOD FOR ERROR DETECTION IN TRANSMISSION UNITS

(71) Applicant: WIKA Alexander Wiegand SE & Co. KG, Klingenberg (DE)

(72) Inventors: Peter Bretz, Burgstadt (DE); Markus Diener, Elsenfeld (DE); Martin Kullmann, Kleinwallstadt (DE)

(21) Appl. No.: 18/526,644

(22) Filed: Dec. 1, 2023

(30) Foreign Application Priority Data
Dec. 6, 2022 (DE) 10 2022 132 391.9

(51) Int. Cl. G05B 19/042

(52) U.S. Cl. CPC G05B 19/0428; G05B 2219/25428

(57) ABSTRACT

The present disclosure relates to a transmission unit for use in measurement technology, a field device, a method for calibration of and/or error detection in a transmission unit, a diagnostic measure and a display unit. The display unit may be or is detachably connected with the evaluation unit, in which at least one diagnostic measure, comprising at least one test of a functionality of the evaluation unit, may be triggered over the display unit and/or the evaluation unit.

### BACKGROUND

The present disclosure relates to a transmission unit for use with a field measurement device. The present disclosure further relates to a method for calibration of and/or error detection in a transmission unit. The present disclosure additionally relates to a diagnostic measure for error detection in a transmission unit and a display unit.

Transmission units are provided for recording and processing measured values of sensors and outputting them according to a uniform method and/or protocol. Industrial systems demand reliable measurement technology. In some implementations, testing of transmission units may be costly to implement, and in some implementations, testing of transmission units may be associated with maintenance and downtime of an industrial system or process plant.

The present disclosure is further based on the technical problem of specifying a novel transmission unit, a novel field device, a novel method for calibration of and/or error detection in transmission units and a novel diagnostic measure and a display unit.

The problem is solved according to the various embodiments of the present disclosure by a transmission unit for use in measurement technology (e.g., in a field device housing). In some implementations, the transmission unit may be paired with an evaluation unit. In some implementations, the evaluation unit may comprise at least one sensor connection, at least one electronic circuit with at least one logic module for processing sensor signals, at least one signal output, and at least one display interface. In some implementations, the transmission unit may comprise a display unit that has a display. In some implementations, the transmission unit may comprise an electronics unit with at least one logic module. In some implementations, the logic module may be detachably connected with the evaluation unit. In some implementations, at least one diagnostic measure, comprising at least one test of a functionality of the evaluation unit, may be triggered through the display and/or the evaluation unit.

Embodiments are disclosed herein relating to a field device having a housing with a cover and a transmission unit with which diagnostic measurements may be triggered locally and/or remotely. In some implementations, diagnostic measurements may be triggered from outside the housing via wireless communication with the display unit, and/or the evaluation unit. In some implementations, diagnostic measurements may be triggered from outside the housing via electronic transmission to the display unit and/or the evaluation unit. In some implementations, diagnostic measurements may be triggered from outside the housing via manual operation of the display unit and/or the evaluation unit.

Embodiments are disclosed herein relating to a method for calibration of and/or error detection in a transmission unit. In some implementations, the transmission unit comprises at least one evaluation unit. In some implementations, the evaluation unit comprises at least one electronic circuit with logic modules, at least one sensor connection and at least one interface for connecting a display unit.

In some implementations, a method is performed by one or more processes to at least perform one diagnostic measurement. In some implementations, the method comprises establishing a connection of the display unit with the evaluation unit of the transmission unit, storing a last measured value of a sensor attached to the evaluation unit, disconnecting the sensor from an electronic circuit of the evaluation unit, connecting at least one test signal and/or at least one test current or at least one reference resistor and/or at least one reference sensor to an electronic circuit of the evaluation unit, performing a target-actual comparison of a test signal received with a target signal and evaluating the test signal received in the display unit and/or the evaluation unit and displaying the result of the target-actual comparison and/or the evaluation on the display and/or a wirelessly coupled mobile terminal.

Embodiments are disclosed herein relating to a method for error detection in a transmission unit using a diagnostic measurement. In some implementations, the method comprises simulating an internal error state of the transmission unit. In some implementations, the method comprises performing a test cycle. In some implementations, the diagnostic measurement is derived from the test cycle. In some implementations, performing the test cycle comprises disconnecting a sensor from a multiplexer, storing a current measured value on the microcontroller and constantly providing the measured value over a signal output for a duration of a test cycle, connecting a reference sensor or a reference resistor or a test signal or a test current, evaluating and reconciling a test value determined with a filed expected value, outputting a test result, reestablishing the connection of the sensor to the multiplexer and transmitting the current measured value at the signal output.

Embodiments are disclosed herein relating to a display for connecting to a transmission unit with an electronics unit, a display unit, and at least one coupling device. In some implementation, a coupling device may comprise an instrument in which electrical signals may be transmitted, such as a data-technical and/or electrical coupling. In some implementations, the coupling device may be coupled with an evaluation unit of the transmission unit. In some implementations, a diagnostic measurement may be triggered using a switching device of the display unit.

### SUMMARY OF THE VARIOUS EMBODIMENTS

A transmission unit for use in measurement technology, for example in a field device housing, may comprise an evaluation unit and a display unit. The evaluation unit may have at least one sensor connection, at least one signal output, and at least one display interface and one electronic circuit. The signal output may be used, for example, for connection to a current loop and/or a bus system. The electronic circuit may comprise at least one logic module for processing sensor signals and is thus designed to process incoming signals.

The display unit may comprise a display and an electronic unit with at least one logic module. The display unit may be detachably connected to the evaluation unit via a connection. The connection may be a mechanical and/or electrical connection, for example a plug connection with power transmission.

According to various embodiments set forth, a transmission unit may comprise least one diagnostic measurement which may be triggered through the display unit and/or the evaluation unit. The diagnostic measurement may comprise at least one test of a functionality of the evaluation unit. Here the diagnostic measure may, for example, be a self-test, in which the internal electronics are tested for errors. The triggering of the diagnostic measure may, for example, occur with the establishment of an electrical connection with the evaluation unit of the transmission unit.

For example, it is possible to carry out a self-test on an evaluation unit with a display unit. By means of a simple plug-in of the display unit, costly disconnection of the evaluation unit from the process may no longer be necessary. Moreover, it is possible in this manner to carry out a self-test on a number of evaluation units one after another with only one display unit, without these having to be disconnected from the process.

In one possible design of the transmission unit, it is provided that the transmission unit is arranged in a housing with a cover. Such an arrangement may be referred to as a field device. A process connection on the housing of the field device may be provided to connect the field device with the evaluation unit of the transmission unit in a sealed manner. Here, for example, the diagnostic measure man be triggered from outside the housing via wireless access to the display unit and/or the evaluation unit and/or via telegram to the display unit and/or the evaluation unit and/or manual operation of the display unit and/or the evaluation unit.

The evaluation unit may, for example, be a temperature transmitter. It may be advantageous to connect a transmitter with a display unit in a field device with a viewing panel. For example, a transmitter with the display is particularly well protected from exterior environmental effects.

In some embodiments of the transmission unit, the display unit may comprise at least one electronic unit and one display. The electronic unit may comprise at least one microcontroller for controlling the diagnostic measure, at least one reference resistor that may, for example, be connected to an electronic circuit of the evaluation unit, and/or a reference sensor connection that may, for example, be designed for the connection of a sensor and for coupling with an electronic circuit of the evaluation unit.

In some embodiments, high-quality reference resistors for the diagnosis and for calibrating may be used. For example, the display unit may use high-quality reference resistors.

Different types of sensors may be connected to the reference sensor connection. The reference sensor connection may generally be regarded as an external reference input. For example, a sensor simulator that may simulate voltage. In some implementations, resistance sensors may be connected to the reference sensor. Alternatively, a reference voltage source, for example a thermoelement or a voltage standard, or a high-precision external reference resistor may be connected.

In some implementations, sensors may be provided in the form of a resistor. For example, a temperature transmitter on the reference sensor connection of the display unit may be provided in the form of a resistor. Connection of a reference resistor or of a high-precision reference sensor (via the reference sensor connection) with the evaluation unit or transmission unit may be through the display unit. By means of the option of connecting many different types of reference sensors or resistors to the evaluation unit, a great deal of flexibility with regard to the diagnostic measure used may be achieved. The transmission unit may remain connected to a facility system and/or process even with the use of different reference sensors or resistors, so that long process down times may be avoided.

The display unit may comprise a display that may, for example, be designed as a liquid crystal display (LCD), field emission display (FED), thin film transistor display (TFT-LCD), cathode ray tube screen (CRT), plasma screen, organic light-emitting diode screen (OLED), screen with light-emitting diodes (LED) or surface conduction electron emitter display (SED). Furthermore, the display may also be provided with a touch-sensitive arrangement for realizing a so-called touch operation, so that operation and optical representation are possible simultaneously.

In some embodiments of the transmission unit, the display unit may be in communication with at least one switching device for activating and deactivating the diagnostic measurement. In some implementations, the display unit may comprise at least one status light to output a status of the diagnostic measurement. In some implementations, the display unit may comprise at least one progress bar to display the progress of the diagnostic measure. In some implementations, the at least one switching device may, for example, be a toggle switch or a button of any embodiment. In some implementations, the switching device may also be activated by touching any field on the display if the display is equipped with touch operation. Various implementations allow simple activation and deactivation of the diagnostic measurement via the display unit and a representation of the status and/or progress thereof.

In some embodiments, the transmission unit is in communication with an evaluation unit having a reference resistor and/or reference sensor. The reference resistor and/or reference sensor may be connected via the at least one switching device of the display unit to an electronic circuit, for example an input circuit, of the evaluation unit. For example, the reference resistor and/or reference sensor may be connected via the display unit. By means of the switching device integrated into the display unit and the additional option of connecting reference sensors to the evaluation unit, a simplified and versatile selection of the diagnostic measures is made possible.

In some embodiments, the transmission unit comprises an adapter via which the display unit may be electronically and/or manually connected to the evaluation unit of the transmission unit. The adapter may, for example, be attached to the housing of the transmission unit and serve as a holder for the display unit. The electrical supply of the display unit may be established starting from the transmission unit via the adapter. In addition to a data connection interface, the adapter may, for example, also secure the display unit within a proximity of the transmission unit. In this way a user need not constantly hold the display unit during the diagnostic measure.

In some implementations, for the wireless transfer of data, it may be advantageous to equip the display unit with its own energy supply, independent of the transmission unit. For example, the display unit may be equipped with an integrated battery. In this manner the overloading of the evaluation unit may be prevented or at least reduced. A further advantage also lies in the flexible, location-independent use of the display unit.

In a further possible design of the transmission unit, it is provided that the diagnostic measure comprises a test cycle, and the test cycle can, upon request via the display unit on at least one sensor input, be initiated or ended from the evaluation unit. Thus, the test cycle need not be stored on memory connected to the evaluation unit and thus, for example, it may be updated especially simply on the display unit, without updating on all evaluation units being required.

In some implementations, aspects of a test cycle may be implemented on and/or derived from an input circuit of the evaluation unit. The input circuit may comprise the at least one sensor input, a microcontroller, and an analog-to-digital converter. The input circuit may be galvanically separated from an output circuit, which is also a component of the evaluation unit. The output circuit may comprise a microcontroller, a digital-to-analog converter, a memory, and an output, in particular, the signal output. From this it results in an advantageous manner that the diagnostic coverage is especially high if the largest possible number of components are covered by the diagnostics. The diagnostic coverage means the percentage of components that are comprised in the diagnosis. In this case, even the sensor input may be tested, which results in an especially high degree of diagnostic coverage for individual components within the system.

In some embodiments, means and measurements for the execution of the test cycle are filed or installed in the evaluation unit and/or the display unit. For example, information on the duration and/or sequence of measures of the test cycle may be filed in the memory of the evaluation unit or a memory of the display unit. Furthermore, information on timing intervals and the characteristics of test cycles executed at intervals may be filed. By means of the integrated memory it may be possible to store and read out an automated digital documentation of the test. The evaluation of these data stored over a longer period may provide information on the (maintenance) status of the transmission unit.

In some embodiments, the evaluation unit and/or the display unit may comprise an interface for wireless communication with a mobile terminal and/or for wireless transmission and storage of data in a cloud, so that communication with the mobile terminal and/or the cloud is easily possible.

In some embodiments, the transmission unit is arranged in the field device housing and the diagnostic measure may be triggered from outside the housing via wireless access to the display unit and/or the evaluation unit and/or via telegram to the display unit and/or the evaluation unit and/or manual operation of the display unit and/or the evaluation unit. Thus, the housing need not be opened to execute the diagnostic measure.

A method according for the calibration of and/or for error detection in a transmission unit and various embodiments of is discussed herein. In some embodiments, the method may be implemented by a transmission unit comprising at least one evaluation unit, the evaluation unit having at least one electronic switch with logic modules, at least one sensor connection and at least one interface for connecting a display unit.

In the method at least one diagnostic measurement is executed, comprising the following steps.

In one step a connection between the display unit and the transmission unit is established. In some implementations, this may be a purely electrical connection and/or a mechanical connection. In some implementations, it is conceivable that a mechanical connection, for example by plugging in the display unit on the transmission unit, and a radio connection for data transmission/data exchange is established between the transmission unit and the display unit.

In a further step, a last-measured measurement value of a connected sensor is stored, in particular in the evaluation unit of the transmission unit. Alternatively, or in addition, the last measurement value in the display unit may be stored. Furthermore, by means of a multiplexer in the evaluation unit, the sensor connected in particular on the input side is disconnected and a reference sensor is connected. The reference sensor may be arranged both in the evaluation unit of the transmission unit and in the display unit.

In a further step, at least one test signal and/or at least one test current and/or at least one reference resistor is/are connected to an electronic circuit of the evaluation unit.

A further step comprises performing a target-actual comparison and evaluating the test signal received in the display unit and/or the evaluation unit.

A result display on the display unit constitutes a further step.

For example, afterward completion of the testing cycle, the transmission unit returns to normal functioning and is ready for normal operation. For example, initially the last-stored measurement value is output on the display unit.

The method makes it possible to perform a self-test on an evaluation unit using a display unit. The costly disconnection of the evaluation unit from the process is no longer necessary. It is also possible in this manner to carry out a self-test on a number of evaluation units one after another with only one display unit, without these having to be disconnected from the process.

In some implementations, the diagnostic measure is triggered via an electrical connection with the display unit. The triggering of the diagnostic measure may occur with the establishment of the electrical connection. Alternatively, or in addition, the diagnostic measure may be triggered via a switching device arranged on the display unit. This allows the simple activation and deactivation of the diagnostic measure via the display unit and a representation of the status and/or progress thereof.

In some implementations, the diagnostic measure is triggered via a wireless connection with the display unit or a mobile terminal. In this design the display unit or the mobile terminal may easily communicate with the evaluation unit of the transmission unit wirelessly and in particular a bidirectional data exchange may take place.

In some implementations, an analog and/or digital test signal is conducted over an input circuit and an output circuit of the evaluation unit. The test signal may, for example, be an analog test current, an analog test voltage or a digital signal. Thus, it may be possible to carry out perform diagnostic measures on different interfaces, e.g., an analog input or even a digital communications interface without additional external test equipment.

In some implementations, the analog and/or digital test signal is measured in the evaluation unit and a target-actual comparison is performed. A result of this comparison is transmitted to the display unit and may thus be easily read by a user on the display.

In some implementations, the diagnostic measure comprises the measurement of an internal temperature of the evaluation unit. Optionally, for the purposes of analysis, this measured temperature may be compared with a temperature measured in the display unit.

In some implementations, the process steps described at the beginning of the claims are performed automatically and/or at intervals, or by hand if needed. For example, the method may be performed daily, once, or multiple times monthly. In addition, performance of the diagnostic measures and/or testing may be done outside of scheduled intervals.

In some implementations, the sequence and/or progress of the diagnostic measure is displayed on a display of the display unit. Furthermore, a result of the diagnostic measure may be stored in a memory of the evaluation unit and/or the display unit. This allows in a simple manner for the representation of the status and/or progress of the diagnostic measure.

In some implementations, upon detection of an error, a status or a warning is output on the display unit. Furthermore, an error signal may also be output acoustically and/or optically and the transmission unit switched to a safe state (functional safety, safety integrity level SIL), so that a so-called remote station (control room) may also run the process in a safe state.

In some implementations, a status and/or progress and a result of the diagnostic measure are transmitted in real time to a mobile terminal and/or to an external memory, in particular to a cloud, and are output and stored by means of the mobile terminal and/or the external memory. This remote access allows maintenance personnel who are deployed to have worldwide access to the to the data determined by the diagnostic measure. Thus, the maintenance personnel need no longer work on site at the device, so that time and costs may be saved.

In a diagnostic measurement for detecting errors in transmission units according to the various embodiments herein, an internal error state is simulated. The diagnostic measurement may be derived from a diagnostic test cycle with the steps: disconnecting a sensor from a multiplexer, storing a current measurement value on the microcontroller and ongoing provision of the measurement value via a signal output during a duration of the test cycle, connecting a reference sensor or a reference resistor or a test signal or a test current, evaluating and reconciling a test value determined with a filed expected value, outputting a test result, reestablishing the connection of the sensor to the multiplexer and transmitting the current measurement value at the signal output.

Performance of error detection may be completed by means of identifying and/or evaluating the diagnostic measurement in a reliable, simple, and thus user-friendly, manner.

In some implementations, the test cycle may be triggered by a switching device on the transmission unit of the evaluation unit and/or a switching device on the display unit and/or via remote access through a mobile terminal by means of the remote access, a location-independent access is enabled, through which time and costs may be saved. In particular, if transmission units (field devices) are used in hazardous or inaccessible locations, a significant increase in safety is possible.

In some implementations, the test result and/or test results are stored in an error memory and/or a status is provided at the signal output and/or a status light is activated. This makes possible in a simple manner the storage of the test results and a representation of the status and/or progress of the diagnostic measure.

A display unit according to the disclosure may be used in transmission units, and comprises an electronic unit and a display unit, in which the display unit may be connected data-technically with an evaluation unit of a transmission unit via at least one coupling device, for example also wirelessly, and/or electrically. At least one of the aforementioned exemplary diagnostic measures may be triggered through a switching device of the display unit.

This allows the simple activation and deactivation of the diagnostic measure via the display unit and/or through the display.

In some embodiments, it is provided that the diagnostic measurement may be triggered through the coupling device of the transmission unit. For example, the diagnostic measure may be triggered already with the establishment of an electrical connection from the display unit with the evaluation unit, without additional switching devices.

In some embodiments, it is provided that a progress and/or result of the at least one diagnostic measurement may be or is displayed on the display of the display unit and may thus be easily read by a user.

In some embodiments, it is provided that the electronic unit has an interface for wireless communication with a mobile terminal, so that with it a simple data-technical coupling is possible. For example, this may be a so-called Bluetooth or LoRaWAN interface.

In some embodiments, the progress and/or the results of the at least one diagnostic measure may be stored in the electronic unit and/or via the interface in a cloud. The location-independent storage of data may reduce electrical components and thus associated costs. Data may be read out worldwide in close to real time and analyzed in international teams.

### BRIEF DESCRIPTION OF THE DRAWINGS

Exemplary embodiments are explained below using drawings wherein like numerals refer to like parts and wherein:

FIG. 1 schematically depicts a transmission unit;

FIG. 2A schematically depicts electrical components and/or assemblies of a transmission unit;

FIG. 2B schematically depicts a simplified block diagram of the assemblies of a transmission unit;

FIG. 3 depicts a simplified diagram of a transmission unit.

### DETAILED DESCRIPTION

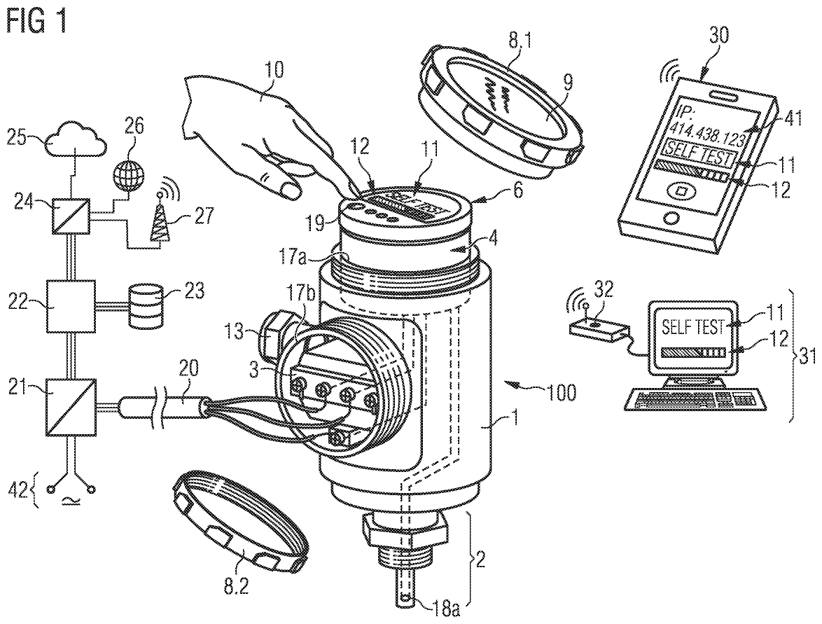

Disclosed in FIG. 1 is an embodiment/design of a transmission unit 100. The transmission unit 100 can, for example, be a field device. A sensor 18a is arranged on a process connection 2 and electrically connected to an evaluation unit 4. The evaluation unit 4 and a display unit 6 are inserted into an opening 17a of a housing 1. As depicted, the display unit 6 is arranged relatively above the evaluation unit 4 and covers it in the installed state. A cover, designed in particular as a screw cover 8.1 with a glass pane 9, closes the opening 17a.

On the display unit 6 various values/data may be displayed. Among these are, for example, a status display 11 and/or a progress bar 12.

The measured values and data may also be transmitted and projected over wires and/or wirelessly to a mobile terminal 30 with a device identification 41 and/or a computer 31. There is also the option to access the transmission unit 100 from the mobile terminal 30 or the computer 31.

In such an embodiment, not only may measured values be retrieved and stored, but diagnostic measures, test cycles or calibrations may be performed as well. For example, a user 10 can, using switches/buttons 19 arranged on the display unit 6, or buttons on the mobile terminal 30, trigger the aforementioned actions, such as for example diagnostic measures, test cycles, calibration. In a diagnostic measure or a test cycle, electrical and/or electronic components of the evaluation unit 4 are tested in the form of a target-actual comparison.

In various embodiments, electrical energy is fed to the transmission unit 100 from a voltage source 42 over a control room connection 21 and a current loop 20 connected therewith. The processing of data from the diagnostics or from normal operation may be done using a server 22. The data may be stored in an intermediate memory 23. Transfer of the data is accomplished in some embodiments over a data interface 24 to a cloud 25, to the world wide web 26 or via radio transmission 27. The connection to the mobile terminal 30 and/or the computer 31 also takes place over these the various described data interface and destinations. The sending and receiving of the data on the computer 31 takes place over a radio module 32.

On one side of the housing 1 another opening 17b may be provided, in which a terminal block 3 of the evaluation unit 4 is arranged. The terminal block 3 is configured for connection to current loops 20 and bus systems. Furthermore, external reference centers may be connected. The opening 17b may be closed with a cover 8.2.

Furthermore, the housing 1 may also comprise in some embodiments a cable outlet 13.

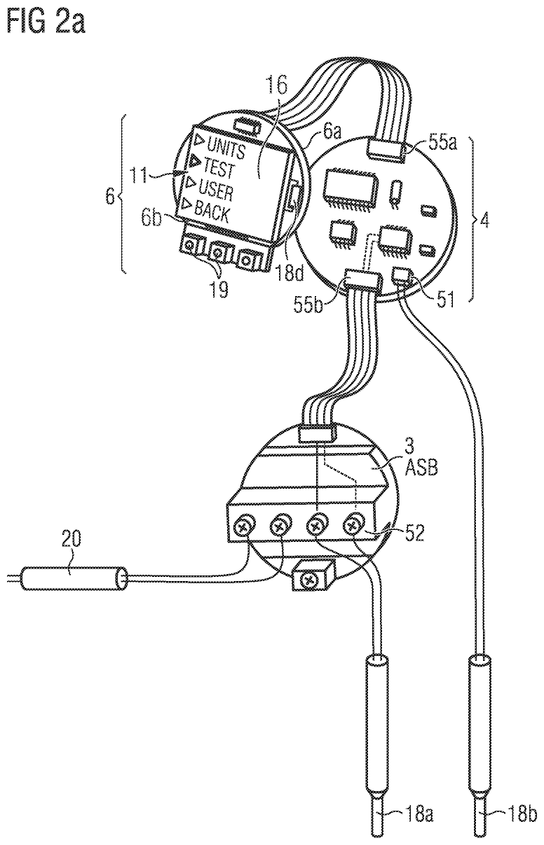

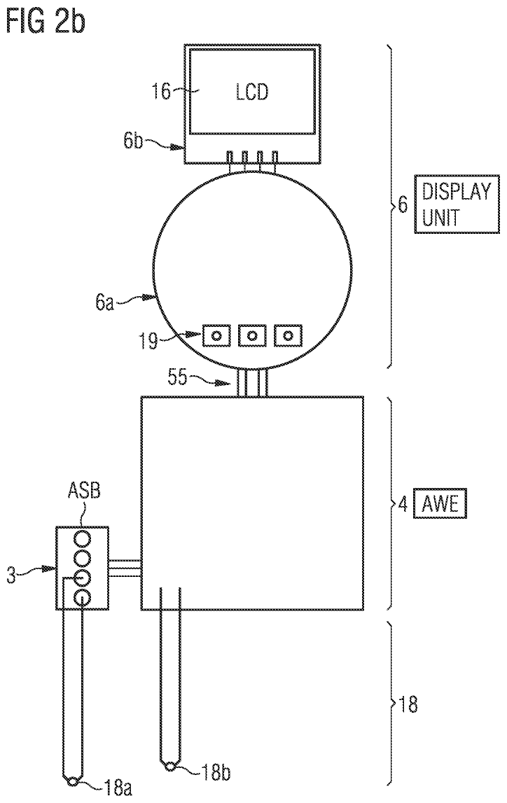

In FIG. 2A an embodiment of the transmission unit 100 is represented schematically.

In addition to its own electronic modules, the evaluation unit 4 may also have connections 55a to the display unit 6 and connections 55b to the terminal block 3, as well as a connection 51 to an external reference sensor 18b. A sensor 18a and a current loop 20 may also be connected to the terminal block 3 using screw terminals 52. The display unit 6 has an electronic unit 6a, a display unit 6b with a display, on which a menu 11, such as a user menu or a status display 11, may be represented. The menu 11 may be navigated using a switch or button 19 and/or programs/actions may be called up and started.

In FIG. 2b a simplified block diagram of the assemblies depicted in FIG. 2a (evaluation unit 4, display unit 6) of the transmission unit 100 is represented.

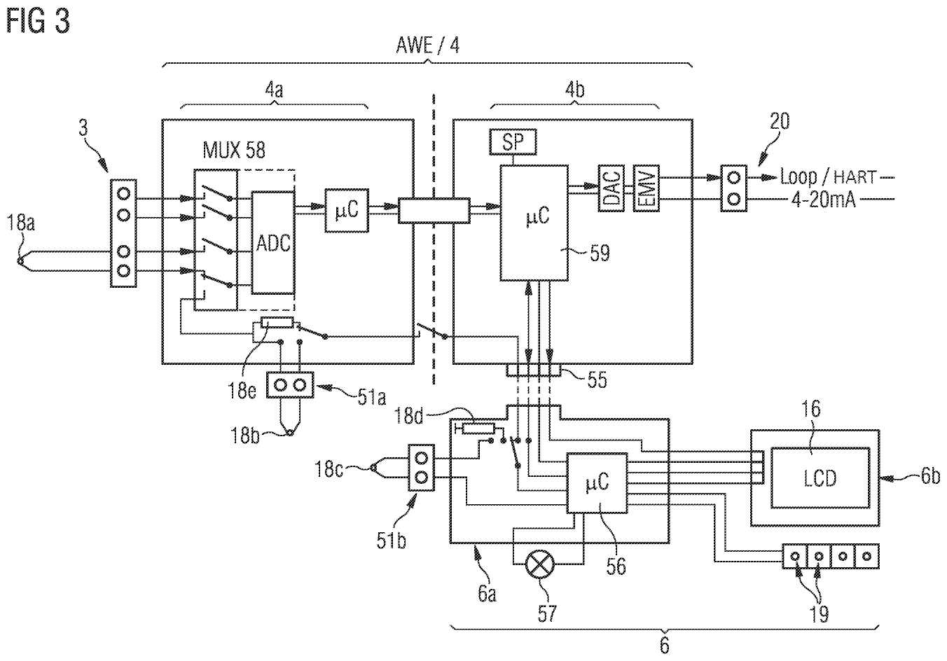

FIG. 3 depicts schematically an embodiment for the wiring of the evaluation unit 4 and the display unit 6.

The evaluation unit 4 comprises a circuit 4a designed as an input circuit and a circuit 4b designed as an output circuit. The input circuit 4a and output circuit 4b may be galvanically separated from one another, which is symbolized by a vertical dotted line between the circuits 4a and 4b.

The evaluation unit 4 may further have connections for at least one sensor 18a, one reference sensor 18b and one current loop 20. The supply of the evaluation unit 4 with electrical power may be accomplished over the current loop 20. Alternatively, a battery, a rechargeable battery or another power source is alternatively available as a means of supplying energy.

The display unit 6 comprises an electronics unit 6a and a display 6b, wherein both units may be connected to one another electrically.

The display unit 6 receives its electrical energy over an interface 55. Furthermore, the interface 55 also serves for data transmission between the evaluation unit 4 and the display unit 6. An energy supply that is independent of the evaluation unit 4 may also be provided, for example in the form of batteries, rechargeable batteries, or the like.

Triggering of the transmission unit for remote access may occur by the at least one switch 19 or via remote access many different modes.

In a normal operating mode of the transmission unit 100 the 18a measures a value of a physical property measure and in particular, an analog measured value is measured, for example a voltage or a resistance, which is then converted by an analog-digital converter ADC of the input circuit 4a to a digital signal. The digital signal passes over the galvanic separation and reaches the output switch 4b. There it may be stored in a memory SP, be transferred over the current loop 20, or shown on the display unit 6.

In a diagnostic mode for testing internal wiring or for calibration of the transmission unit 100 the at last one switch/button 19 may likewise activated. The sensor 18a is separated from the input circuit 4a by activating a multiplexer 58. The last measured value of the sensor 18a is stored in the memory SP. Simultaneously or shortly thereafter a test current and/or a test signal may be triggered. Optionally, a reference sensor 18c or a reference resistor 18d may be connected thereto.

The test current and/or the test signal may be passed from the electronics unit 6a over the interface 55, the output circuit 4b and the galvanic separation, into the input circuit 4a of the transmission unit 100. The test current and/or the test signal may then passed through the input circuit 4a over the multiplexer 58, the analog-to-digital converter ADC and a microcontroller μC.

In other examples, in addition to or instead of the reference sensor 18c or the reference resistor 18d, a reference resistor 18e fixedly installed in the input circuit 4a or a connectable reference sensor 18b may also be added.

The two connections 51a, 51b are in general to be regarded as external reference inputs. For example, a sensor simulator that may simulate voltage or resistance sensors may be connected there. However, this may also be realized through a novel reference module that comprises such functions. Alternatively, a reference voltage source, for example a thermoelement or a voltage standard, or a high-precision external reference resistor, may also be connected thereto.

After the test current and/or the test signal has passed through the input circuit 4a, it passes through another microcontroller 59 on the output circuit 4b, before the test current or the test signal once again arrives back at the display unit 6.

Processing of the incoming test current and/or test signal may optionally be undertaken in the microcontroller 59 of the output circuit 4b as well as in the microcontroller 56 of the electronics unit der 6a. Here the processing comprises at least substantially one reconciliation of the set and received test current and/or test signal. A result of the processing may be reflected on the display 16. Alternatively, it is also possible to output the result over the current loop 20 for further processing or storage, for example in a cloud 25 pursuant to FIG. 1.

The present disclosure is not limited to the preceding detailed exemplary embodiments. It may be modified in the scope of the following claims. Likewise, individual aspects of the subordinate claims may be combined with one another.

1. A transmission unit for use in a field device housing, the transmission unit comprising:
an evaluation unit including:
at least one sensor connection,
an electronic circuit with at least one logic module,
wherein the at least one logic module processes for processing sensor signals,
at least one signal output, and
at least one display interface; and
a display unit including:
a display and an electronics unit including at least one other logic module,
wherein the display unit is detachably connected with the evaluation unit, and
wherein the display unit and/or the evaluation unit triggers at least one diagnostic measurement, including at least one test of a functionality of the evaluation unit.

2. The transmission unit of claim 1, wherein the display unit includes:
at least one electronics unit with at least one microcontroller,
wherein the at least one microcontroller controls the at least one diagnostic measurement,
at least one reference resistor connected to an electronic circuit of the evaluation unit, and/or
at least one reference sensor connection, wherein the at least one reference sensor connection connects a sensor with the electronic circuit of the evaluation unit; and
at least one display.

3. The transmission unit of claim 1, wherein the display unit includes:
at least one switching device, wherein the switching device activates and deactivates the at least one diagnostic measurement;
at least one status light to output a status of the at least one diagnostic measurement; and/or
at least one progress bar to display progress of the at least one diagnostic measurement.

4. The transmission unit of claim 1, wherein the evaluation unit includes:
a reference resistor connected via a switching device of the display unit to an electronic circuit of the evaluation unit; and/or
a reference sensor connected via a switching device of the display unit to an electronic circuit of the evaluation unit.

5. The transmission unit of claim 1, wherein the transmission unit includes:
an electrical or mechanical connection of the display unit with the evaluation unit.

6. The transmission unit of claim 1, wherein triggering the at least one diagnostic measurement initiates a test cycle, and wherein the at least one diagnostic measurement, upon request via the display unit, is triggered or ended via the evaluation unit.

7. The transmission unit of claim 6, wherein the evaluation unit and/or the display unit include at least one control unit, and wherein the at least one control unit performs the test cycle.

8. The transmission unit of claim 1, wherein the evaluation unit and/or the display unit include at least one wireless communication interface, and wherein the wireless communication interface communicates with a mobile terminal and/or communicates data to an external memory.

9. The transmission unit of claim 1, wherein the display unit is a mobile terminal wirelessly and/or directly coupled with the evaluation unit.

10-27. (canceled)

28. A transmission unit for use in a field device housing, the transmission unit comprising:
an evaluation unit including:
a sensor connection,
a electronic circuit with at least one logic module, wherein the at least one logic module processes sensor signals,
a signal output, and
a display interface; and
a display unit, detachably connected with the evaluation unit, the display unit including:
a display and an electronics unit including the at least one logic module, wherein the display unit and/or the evaluation unit triggers a diagnostic measurement.

29. The transmission unit of claim 28, wherein the display unit includes:
at least one microcontroller, wherein the at least one microcontroller controls the diagnostic measurement,
at least one reference resistor connected to an electronic circuit of the evaluation unit, and/or
at least one reference sensor connection, wherein the at least one reference sensor connection connects a sensor with the electronic circuit of the evaluation unit.

30. The transmission unit of claim 1, wherein the display unit includes:
at least one switching device, wherein the switching device activates and deactivates the diagnostic measurement;
at least one status light to output a status of the diagnostic measurement; and/or
at least one progress bar to display progress of the diagnostic measurement.

31. The transmission unit of claim 1, wherein the evaluation unit includes:
a reference resistor connected via a switching device of the display unit to an electronic circuit of the evaluation unit; and/or
a reference sensor connected via a switching device of the display unit to an electronic circuit of the evaluation unit.

32. The transmission unit of claim 28, wherein triggering the diagnostic measurement initiates a test cycle, and wherein the diagnostic measurement is triggered or ended via the evaluation unit.

33. The transmission unit of claim 32, wherein the evaluation unit includes at least one control unit, and wherein the at least one control unit performs the test cycle.

34. The transmission unit of claim 28, wherein the evaluation unit includes at least one wireless communication interface, and wherein the wireless communication interface communicates with a mobile terminal and/or communicates data to an external memory.

35. The transmission unit of claim 28, wherein the display unit is a mobile terminal wirelessly and/or directly coupled with the evaluation unit.

36. A method for use with a transmission unit in a field device housing, the method comprising:
storing, on at least one microcontroller, a reference value associated with a sensor;
receiving, from a display and/or evaluation unit, a triggering input;
initializing, in response to the triggering input, a diagnostic measurement,
wherein the at least one microcontroller controls the diagnostic measurement,
wherein the diagnostic measurement tests a functionality of the evaluation unit,
wherein initializing the diagnostic measurement includes initializing a test cycle comparing the reference value to a current value;
generating, based on the diagnostic measurement, a result; and
transmitting the result to a device.

37. The method of claim 36, wherein the triggering input is received from the device or another device.

38. The method of claim 36, wherein the device is a remote device.

39. The method of claim 36, further comprising:
rendering, at the device and based on transmitting the result to the device, the result.
